(19) United States
(12) Patent Application Publication
(10) Pub. No.: US 2015/0171869 A1
(43) Pub. Date: Jun. 18, 2015

(54) CIRCUIT AND METHOD OF CONTROLLING A CIRCUIT

(71) Applicant: FUJITSU LIMITED, Kawasaki-shi (JP)

(72) Inventor: Masaru Takehara, Yokohama (JP)

(73) Assignee: Fujitsu Limited, Kawasaki (JP)

(21) Appl. No.: 14/530,273

(22) Filed: Oct. 31, 2014

(30) Foreign Application Priority Data
Dec. 18, 2013 (JP) 2013-261751

(51) Int. Cl. H03K 19/177; G11C 11/419

(52) U.S. Cl. CPC H03K 19/17764; H03K 19/1776; G11C 11/419

(57) ABSTRACT

A circuit includes a memory including a first and a second memory region each configured to store coupling information, a first logic circuit including a plurality of first logic elements coupled with each other based on the coupling information stored in the first memory region, a second logic circuit including a plurality of second logic elements coupled with each other based on the coupling information stored in the second memory region, a writing circuit configured to write the coupling information in each of the first and the second memory region when a first output data of the first logic circuit does not identify to a second output data of the second logic circuit, and a determination circuit configured to determine whether or not the first output data identifies to the second output data after the coupling information is written in each of the first and the second memory region.

### CROSS-REFERENCE TO RELATED APPLICATION

This application is based upon and claims the benefit of priority of the prior Japanese Patent Application No. 2013-261751, filed on Dec. 18, 2013, the entire contents of which are incorporated herein by reference.

### FIELD

The embodiment discussed herein is related to a circuit and a method of controlling a circuit.

### BACKGROUND

Logic devices programmed with logic specifications are used to realize a various kinds of logic circuits. Such devices are collectively referred to as a Programmable Logic Device (PLD) and a Field Programmable Gate Array (FPGA) is known as an example. The FPGA is configured by combining a plurality of logic elements with wire elements and switching elements that are capable of variably controlling coupling states of these logic elements. The wire element and the switching element couple the logic elements according to coupling information specifying a coupling relationship of multiple logic elements. Various logic circuits can be realized by changing the coupling information on the circuits including FPGAs.

In general, the FPGA includes a memory region to store coupling information. The coupling information stored in the memory region is used to determine a coupling relationship of the logic elements of the FPGA. In other words, a logic circuit with a desired specification is achieved by writing specific coupling information in the memory.

However, when the memory, in which the coupling information is written, is subjected to electric noise and the like, a logical value stored in a storage element of the memory is unintentionally inverted and the coupling information is changed. This error is caused not because a physical failure occurs in a logic circuit but because the coupling information is accidentally rewritten in the memory, which is thus called a soft error. When a soft error occurs in the memory region in the FPGA, the coupling relationship of the logic elements is changed according to the result of the error. Thus, a logic operation is wrongly performed.

To solve this problem, there is a known technique in which coupling information stored in a memory is periodically read and a CRC check and the like are performed on the coupling information as an error check. Furthermore, there is a known technique that when an error is detected in coupling information stored in a memory, the coupling information is rewritten to correct data stored in the memory, so that a logic circuit is reconfigured. The related art documents include Japanese Laid-open Patent Publication Nos. 2005-235074 and 2006-53873.

### SUMMARY

According to an aspect of the invention, a circuit includes a memory including a first memory region and a second memory region each configured to store coupling information specifying a coupling relationship of a plurality of logic elements, a first logic circuit including a plurality of first logic elements included in the plurality of logic elements which are coupled with each other based on the coupling information stored in the first memory region, a second logic circuit including a plurality of second logic elements included in the plurality of logic elements which are coupled with each other based on the coupling information stored in the second memory region, a writing circuit configured to write the coupling information in each of the first memory region and the second memory region when a first output data of the first logic circuit based on a first input data into the first logic circuit does not identify to a second output data of the second logic circuit based on the first input data into the second logic circuit, and a determination circuit configured to determine whether or not the first output data identifies to the second output data after the coupling information is written in each of the first memory region and the second memory region.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a hardware configuration of a system including a PLD in an embodiment;

FIG. 2 is a diagram illustrating the configuration of an FPGA programmable logic circuit in the embodiment;

FIG. 3 is a diagram illustrating the configuration of a logic circuit which is formed by the programmable logic circuit in the embodiment;

FIG. 4 is a diagram illustrating a coupling relationship between address regions of a memory and logic circuits each formed by using the programmable logic circuit in the embodiment;

FIG. 5 is a diagram illustrating a detailed logic circuit in the embodiment;

FIG. 6 is a diagram illustrating a detailed combined circuit in the embodiment;

FIG. 7 is a diagram illustrating a coupling relationship between an active logic circuit and address regions of the memory in the embodiment;

FIG. 8 is a functional block diagram of a control circuit in the embodiment;

FIG. 9 is a circuit configuration diagram of a combinational circuit when an arithmetic circuit is switched to a standby circuit;

FIG. 10 is a processing flowchart performed by the control circuit in the embodiment;

FIG. 11 is a table illustrating a coupling relationship between information which is used by determining a determination circuit and determination results in the embodiment;

FIG. 12 is a diagram illustrating an example circuit configuration of the determination circuit in the embodiment;

FIG. 13 is a diagram illustrating an example circuit configuration of a comparison circuit in the embodiment;

FIG. 14 is a diagram illustrating an example circuit configuration of a selection circuit in the embodiment;

FIG. 15 is a diagram illustrating a modification of a logic circuit in the embodiment; and

FIG. 16 is a diagram illustrating a utility form of the FPGA in the embodiment.

### DESCRIPTION OF EMBODIMENT

There is a case where a physical failure other than a soft error occurs in a logic element, a switching element, and the like, which are included in an FPGA. The physical failure is a case, for example, a transistor element included in a logic element or a switching element is thermally broken down and does not operate properly. The physical failure of the element is referred to as a hard error. When such a hard error occurs in the FPGA, even if the coupling information is correctly stored in the memory, a logic circuit with coupling information is not configured correctly. This results in an occurrence of an error in an arithmetic result. Thus, only by checking whether or not a soft error occurs in the coupling information stored in the memory, it is not determined whether or not an arithmetic result by the logic circuit is correct.

According to the present embodiment, both cases where a hard error occurs in a logic element or a switching element in a PLD such as an FPGA and where a soft error occurs in coupling information stored in a memory are detected. Thus, it can be determined whether a current error is a soft error or a hard error.

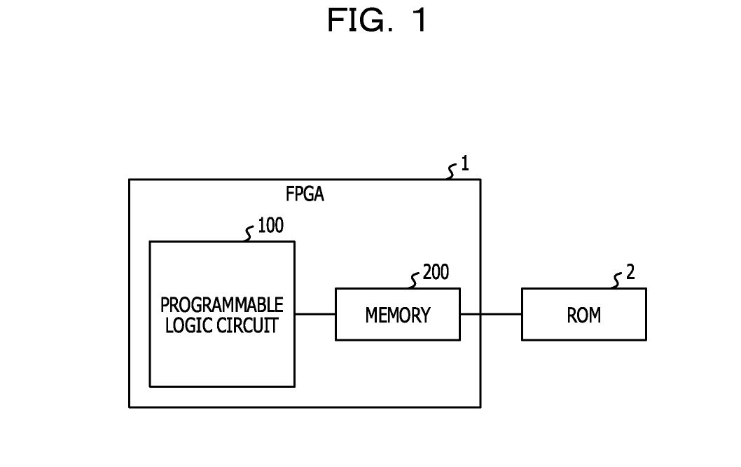

FIG. 1 is a hardware configuration of a system including a PLD in the present embodiment. The system disclosed in FIG. 1 includes an FPGA 1, and a Read Only Memory (ROM) 2 coupled with the FPGA 1. The FPGA 1 is an example of the PLD. The ROM 2 is an example of a memory device and includes a nonvolatile memory chip such as an Erasable Programmable Read Only Memory (EPROM), an Electrically Erasable Programmable Read Only Memory (EEPROM), and a flash memory. The ROM 2 stores coupling information on a logic circuit including the FPGA 1.

The FPGA 1 has a programmable logic circuit 100 and a memory 200. The coupling information stored in the ROM 2 is written in the memory 200. The programmable logic circuit 100 configures a predetermined logic circuit based on the coupling information written in the memory 200.

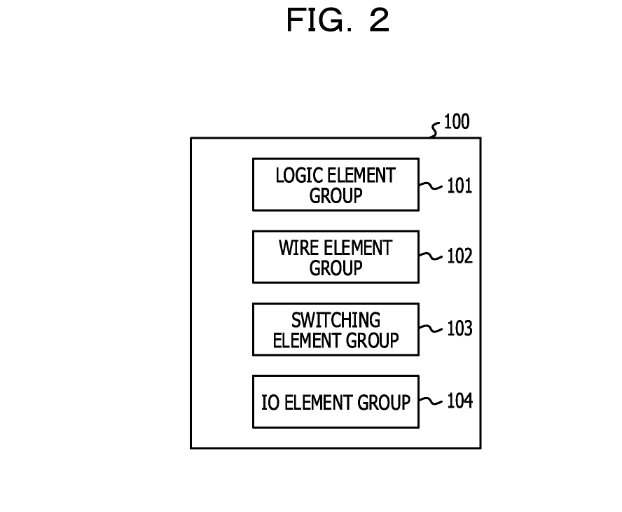

FIG. 2 is a diagram illustrating the configuration of the programmable logic circuit 100 of the FPGA 1. The programmable logic circuit 100 includes a logic element group 101, a wire element group 102, a switching element group 103, and an Input Output (IO) element group 104. The logic element group 101 includes logic elements such as a NOT element (inverter), an AND element, an OR element, a NAND element, a NOR element, and a lookup table. The wire element group 102 includes a wire element made of polysilicon or a metal. The switching element group 103 includes switching elements such as a Metal Oxide Silicon (MOS) transistor and a bipolar transistor. The coupling information written in the memory 200 is information which specifies how the logic elements are coupled with each other using the switching elements and the wire elements. Based on the coupling information, the logic elements are coupled with each other by using the switching elements and the wire elements, so that a desired logic circuit is formed. The IO element group 104 includes an IO element configured to control input and output of data to the logic elements.

In a case that data is inputted into the logic circuit including the FPGA 1 with such a configuration and a result of the logic operation is outputted, a cause of occurrence of an error in the output data may include a soft error in the coupling information specifying the coupling relationship of the logic elements. The coupling information on the logic elements in the FPGA 1 is written in the memory 200. For example, a Static Random Access Memory (SRAM) may be used as the memory 200. The SRAM holds data by latching a logical value of “1” or “0” in a flip-flop storage element. When the SRAM is subjected to electric noise, a so-called soft error may be caused, in which the logical value stored in the storage element may be inverted. When the data written in the memory 200 is rewritten, the coupling state of the logic elements is changed based on the rewritten data and the logic circuit wrongly performs an operation. For this reason, when a soft error occurs in the coupling information written in the memory 200, correct coupling information has to be written in the memory 200 again to return the stored value to a correct one.

In the logic circuit formed with the FPGA 1, other factors causing an error in output data may include a physical failure, so-called a hard error, that is caused in a logic element or the like. For example, this is such a failure that a transistor included in an inverter element, for example, is broken down and an inverted signal becomes impossible to be outputted in response to a received signal. In this case, the broken element is never recovered and never becomes usable. For this reason, even when the coupling information is rewritten in the memory 200, the circuit is incapable of being recovered, and thus the broken element has to be replaced by another element. In this manner, when an error is detected in the output data of the logic circuit, as the causes of the error, there are at least two possible causes of a soft error and a hard error. Thus, for its recovery, there are different countermeasures for respective causes.

Described in the following description are in the order of a configuration example of a logic circuit which is achieved by the FPGA 1, a method of detecting that output data of a logic circuit includes an error, and a recovery method when an error is detected.

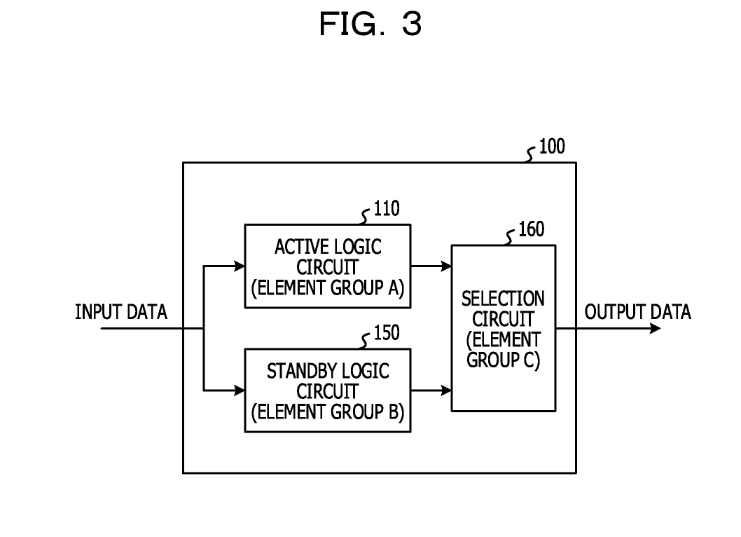

FIG. 3 illustrates an example configuration of the logic circuit formed by the logic elements, the wire elements, the switching elements, and the like which are included in the programmable logic circuit 100 illustrated in FIG. 2. This is an example in which logic circuits are duplicated and one is used as an active logic circuit 110 and the other is used as a standby logic circuit 150 in order to enhance availability of arithmetic processing by the logic circuit. The active logic circuit 110 is formed by an element group A included in the programmable logic circuit 100 and the standby logic circuit 150 is formed by an element group B included in the programmable logic circuit 100. The term “element group” is used as a term comprehensively encompassing a logic element, a wire element, a switching element, and an IO element. The active logic circuit 110 and the standby logic circuit 150 are formed as logic circuits with the same circuit configuration based on the same coupling information. Additionally, the same data is received by the active logic circuit 110 and the standby logic circuit 150 and the same logic operation is performed. An output of the active logic circuit 110 and an output of the standby logic circuit 150 are received by the selection circuit 160. When any error occurs in the active logic circuit 110 and data is incapable of being outputted, or when the output data from the active logic circuit 110 includes an error, the active logic circuit 110 is switched to the standby logic circuit 150. After that, the selection circuit 160 switches standby logic circuit 150 to the active logic circuit 110 after a recovery operation is performed on the active logic circuit 110. It is noted that the selection circuit 160 is formed by an element group C included in the programmable logic circuit 100.

In this manner, with the redundancy of the logic circuit, when it is detected that output data of one of the logic circuits includes an error, the selection circuit 160 switches the one of the logic circuits to the other logic circuit, so that the output as the entire FPGA 1 may be maintained and a countermeasure for the logic circuit in which an error occurs may be made.

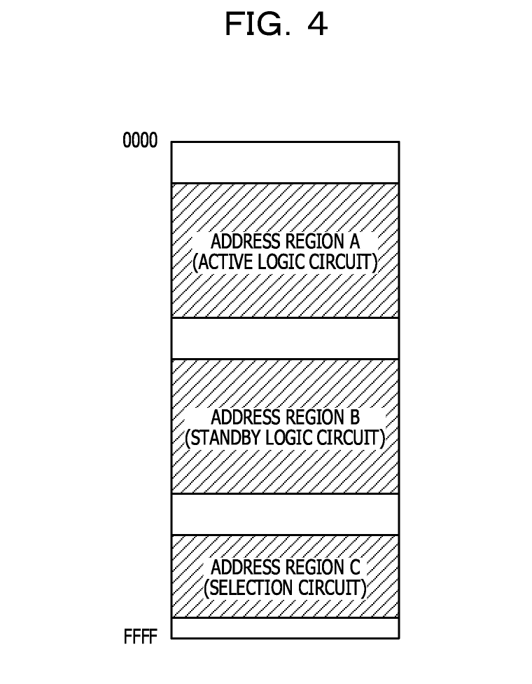

FIG. 4 is a diagram illustrating a coupling relationship between the address regions of the memory 200 and the logic circuit formed by the programmable logic circuit 100. The address regions of the memory 200 and the regions of the programmable logic circuit 100 have a one-to-one correspondence. The address region A of the memory 200 in FIG. 4 is a region storing the coupling relationship of the elements included in the element group A in FIG. 3. The logic element, the wire element, the switching element, and the IO element, which are included in the element group A, are coupled according to the coupling information stored in the address region A, so that the active logic circuit 110 is configured. Similarly, the logic element, the wire element, the switching element, and the IO element, which are included in the element group B, are coupled according to the coupling information stored in the address region B, so that the standby logic circuit 150 is configured. Also, the logic element, the wire element, the switching element, and the IO element, which are included in the element group C, are coupled according to the coupling information stored in the address region C, so that the selection circuit 160 is configured.

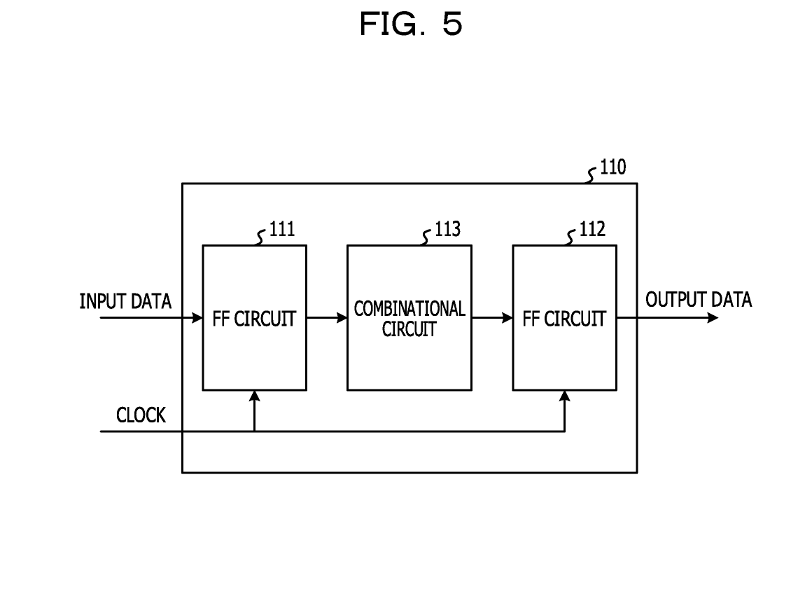

FIG. 5 is a diagram illustrating a detailed circuit configuration of the active logic circuit 110 or the standby logic circuit 150 in FIG. 3. Here, the active logic circuit 110 is explained as an example, but the explanation is applicable to the standby logic circuit 150. The active logic circuit 110 includes flip-flop circuits (hereinafter, FF circuits) 111 and 112 and a combinational circuit 113. The FF circuits 111 and 112 are a circuit that latches input data in synchronization with a clock and outputs and inputs the data latched in synchronization with a clock. For example, a D-type FF circuit or a RS-type FF circuit is applicable. The combinational circuit 113 is a circuit in which output is settled depending on a state of data to be inputted. For example, the combinational circuit 113 is formed by combining an AND element, an OR element, and the like.

In the example illustrated in FIG. 5, the combinational circuit 113 is arranged between the FF circuit 111 and the FF circuit 112. Data inputted to the active logic circuit 110 is latched by the FF circuit 111. The data latched by the FF circuit 111 is inputted to the combinational circuit 113 and the combinational circuit 113 outputs an arithmetic result in response to the received data to the FF circuit 112. The FF circuit 112 latches the arithmetic result received from the combinational circuit 113. It is noted that another combinational circuit may be provided after the FF circuit 112.

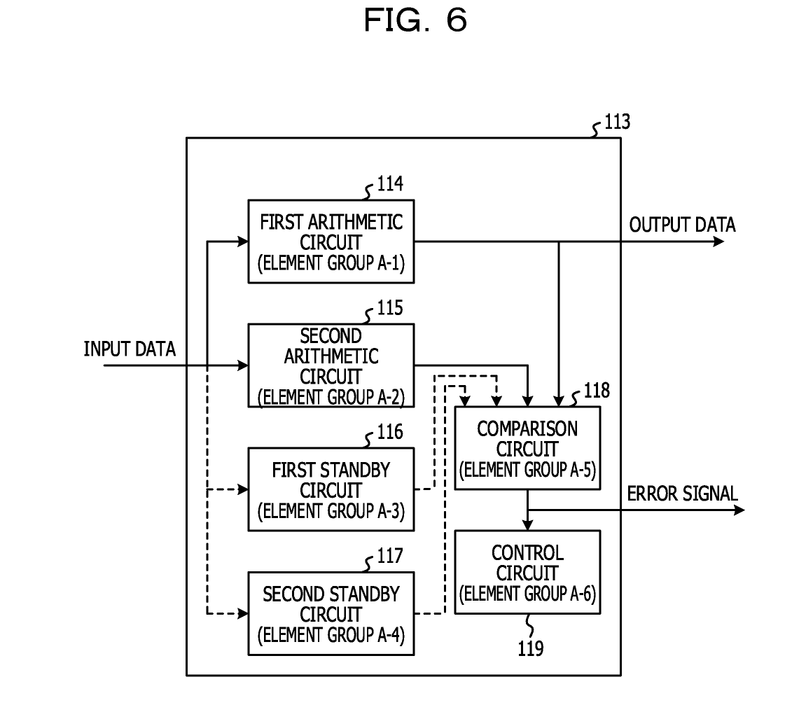

FIG. 6 is a diagram illustrating further in detail the combinational circuit 113 disclosed in FIG. 5. The combinational circuit 113 includes a first arithmetic circuit 114, a second arithmetic circuit 115, a first standby circuit 116, a second standby circuit 117, a comparison circuit 118, and a control circuit 119. The first arithmetic circuit 114 is formed by an element group A-1. The second arithmetic circuit 115 is formed by an element group A-2. The first standby circuit 116 is formed by an element group A-3. The second standby circuit 117 is formed by an element group A-4. The comparison element 118 is formed by an element group A-5. The control circuit 119 is formed by an element group A-6.

The first arithmetic circuit 114 and the second arithmetic circuit 115 are provided in parallel and receive the same input data. Also, the first arithmetic circuit 114 and the second arithmetic circuit 115 is an arithmetic circuit which is formed by the same coupling information written in the address region A-1 and the address region A-2 of the memory 200 to be described later and is configured to output the same output data as long as a soft error or a hard error does not occur.

When a hard error occurs in a logic element or the like which is included in the first arithmetic circuit 114, the first standby circuit 116 is used as a substitute for the first arithmetic circuit 114. Similarly, when a hard error occurs in a logic element or the like which is included in the second arithmetic circuit 115, the second standby circuit 117 is used as a substitute for the second arithmetic circuit 115. Accordingly, when a hard error does not occur in a logic element or the like which is included in the first arithmetic circuit 114, the first standby circuit 116 does not perform arithmetic processing even after input data is received, and an arithmetic result is not outputted. Similarly, when a hard error does not occur in a logic element or the like which is included in the second arithmetic circuit 115, the second standby circuit 117 does not perform arithmetic processing even after input data is received, and an arithmetic result is not outputted.

The comparison circuit 118 compares the output data of the first arithmetic circuit 114 with the output data of the second arithmetic circuit 115. When values of both data are not the same, an error signal is outputted. In other words, the comparison circuit 118 is a circuit configured to create an error signal when a hard error occurs in at least one of the first arithmetic circuit 114 and the second arithmetic circuit 115 or when a soft error occurs in at least one of the address region A-1 and address region A-2 of the memory 200. The control circuit 119 performs error-type determination and recovery operation for the error after the error signal is received from the comparison circuit 118.

It is noted that, although it is not illustrated, a first switching circuit configured to switch whether input data is inputted to the first arithmetic circuit 114 and the second arithmetic circuit 115 or input data is inputted to the first standby circuit 116 and the second standby circuit 117 may be further provided. Although it is also not illustrated, a second switching circuit configured to switch whether an output of the first arithmetic circuit 114 and an output of the second arithmetic circuit 115 are inputted to the comparison circuit 118 or an output of the first standby circuit 116 and an output of the second standby circuit 117 are inputted to the comparison circuit 118 may be further provided.

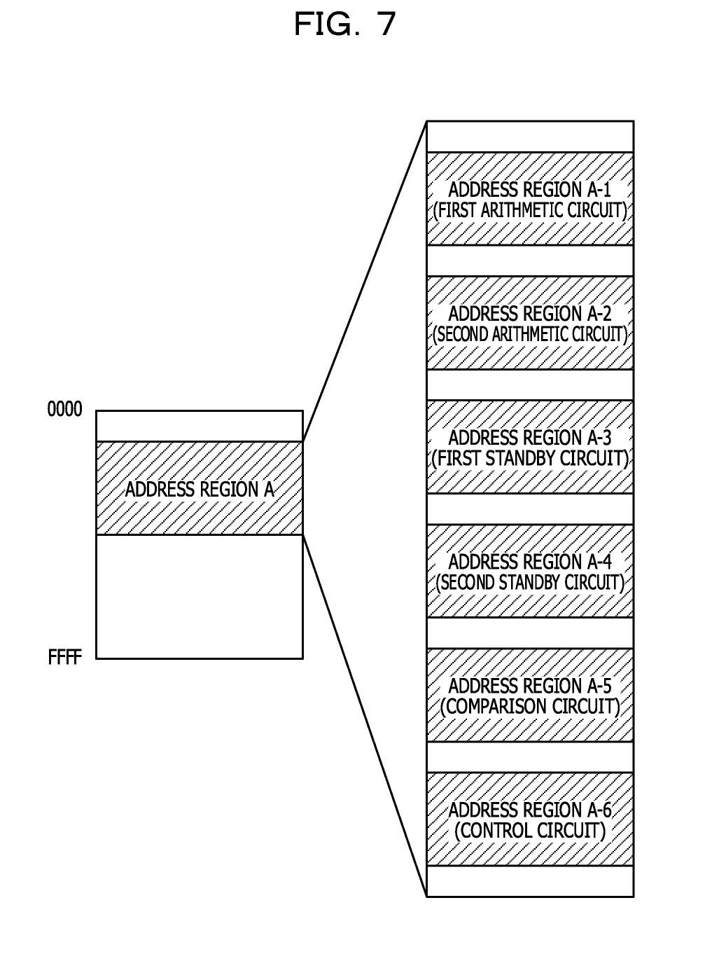

FIG. 7 is a diagram illustrating a coupling relationship between the combinational circuit 113 in FIG. 6 and the address regions of the memory 200. The address regions in FIG. 7 are equivalent to detail of the address regions A in FIG. 4. The coupling information of an element group A-1 configuring the first arithmetic circuit 114 is written in an address region A-1. The coupling information of an element group A-2 configuring the second arithmetic circuit 115 is written in an address region A-2. The coupling information of an element group A-3 configuring the first standby circuit 116 is written in an address region A-3. The coupling information of an element group A-4 configuring the second standby circuit 117 is written in an address region A-4. The coupling information of an element group A-5 configuring the comparison circuit 118 is written in an address region A-5. The coupling information of an element group A-6 configuring the control circuit 119 is written in an address region A-6. In this manner, the element groups of the programmable logic circuit 100 and the address regions of the memory 200 have one-to-one correspondence. For example, when a soft error occurs in the address region A-1, the coupling state of the first arithmetic circuit 114 is changed. When a soft error occurs in the address region A-2, the coupling state of the second arithmetic circuit 115 is changed.

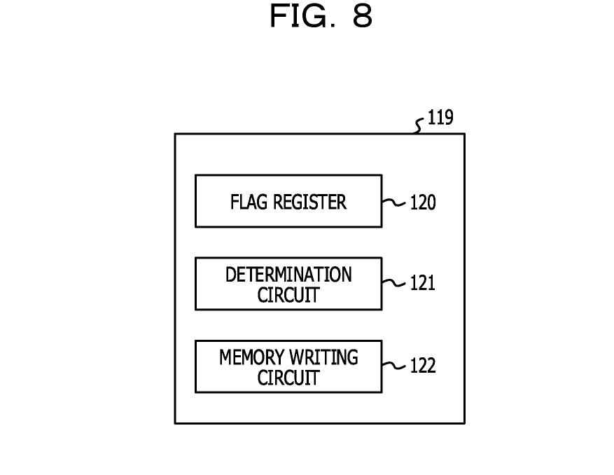

FIG. 8 is a functional block diagram of the control circuit 119. The control circuit 119 receives the error signal from the comparison circuit 118 and performs various kinds of controls. The control circuit 119 has a flag register 120, a determination circuit 121, and a memory writing circuit 122. The flag register 120 is a register configured to create and store an error flag after the error signal is received from the comparison circuit 118. In addition, the flag register 120 erases the error flag after the error signal from the comparison circuit 118 is resolved. The determination circuit 121 is a circuit configured to perform determination based on the error signal which is outputted from the comparison circuit 118 and a value stored in the flag register 120. The memory writing circuit 122 performs control of writing the coupling information in the address region A-1, address region A-2, address region A-3, and address region A-4 of the memory 200 based on the result determined by the determination circuit 121. It is noted that to store and erase the error flag in the flag register 120 are performed after the determination operation by the determination circuit 121.

Hereinafter, the operations of the flag register 120, the determination circuit 121, the memory writing circuit 122 are described. Firstly, assumed is a state where a soft error and a hard error do not occur in the first arithmetic circuit 114 and the second arithmetic circuit 115, and each of the first arithmetic circuit 114 and the second arithmetic circuit 115 outputs the same arithmetic result. In this case, the error signal is not outputted from the comparison circuit 118 and the error flag is not stored in the flag register 120. In this state, when a soft error or a hard error occurs in the first arithmetic circuit 114 and the second arithmetic circuit 115, the comparison circuit 118 creates and outputs an error signal. When the error signal is received, the determination circuit 121 reads the contents of the flag register 120 at that time point. As assumed above, at this point, an error flag is not stored in the flag register 120 yet. Accordingly, the determination circuit 121 determines that there has been no error in the first arithmetic circuit 114 or the second arithmetic circuit 115 by that time but an error has just occurred at that time point. Based on the determination result, the memory writing circuit 122 rewrites the coupling information in the address region A-1 and the address region A-2 which respectively correspond to the first arithmetic circuit 114 and the second arithmetic circuit 115. This is because when the error is a soft error, the rewriting the coupling information allows recovery from the error state to a normal state. Then, the error flag is stored in the flag register 120.

When the output of the error signal from the comparison circuit 118 is terminated by rewriting the coupling information in the address region A-1 and the address region A-2, the determination circuit 121 determines that the error state is recovered. In other words, when the error signal from the comparison circuit 118 is 0 and the error flag is stored in the flag register 120, the determination circuit 121 determines that the error is resolved based on the fact that the error signal was received in the previous determination but the error signal is not received in this determination. On the other hand, when the error signal is received from the comparison circuit 118 even after the coupling information is rewritten, the determination circuit 121 determines that a cause of the error is not a soft error but a hard error. In other words, the case where the error flag is stored in the flag register 120 and the error signal is received from the comparison circuit 118 has such a meaning that the error signal is received again after the previous determination. Thus, it is determined that the error is a hard error. Then, in place of the first arithmetic circuit 114 and the second arithmetic circuit 115, the first standby circuit 116 and the second standby circuit 117 are used to reconstruct the active logic circuit 110. Accordingly, in either case of a soft error and a hard error, the logic circuit may be recovered.

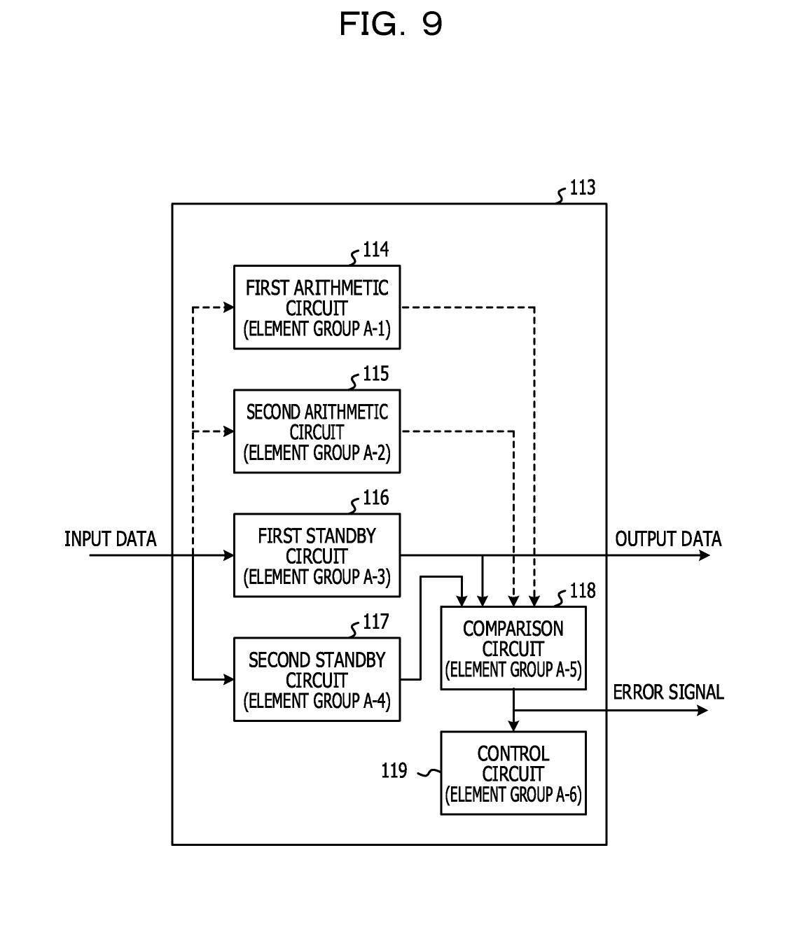

FIG. 9 is a circuit configuration diagram of the combinational circuit 113 when the first arithmetic circuit 114 and the second arithmetic circuit 115 are respectively switched to the first standby circuit 116 and the second standby circuit 117. The output of the FF circuit 111 is coupled with the first standby circuit 116 and the second standby circuit 117 and the output of the first standby circuit 116 is transmitted to the FF circuit 112. Also, the comparison circuit 118 compares the output results of the first standby circuit 116 and the second standby circuit 117.

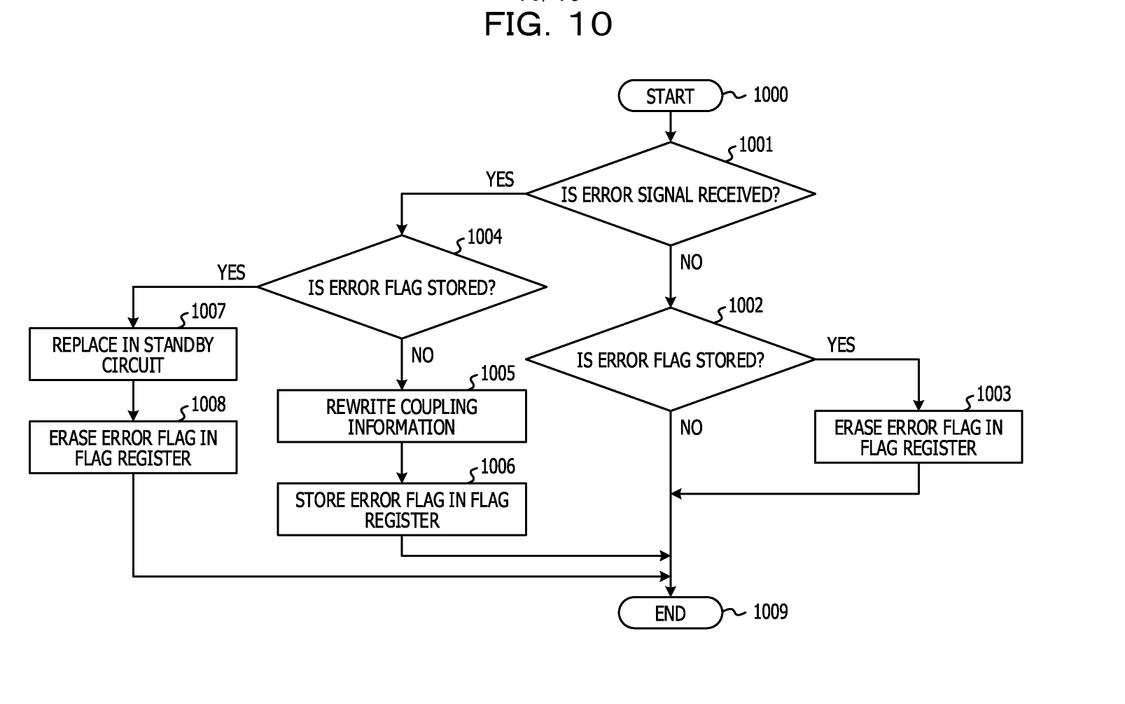

FIG. 10 is a processing flowchart by the control circuit 119. The control circuit 119 starts the processing flow from step 1000. At step 1001, the determination circuit 121 determines if an error signal is received from the comparison circuit 118. When it is determined at step 1001 that an error signal is not received from the comparison circuit 118 (No at step 1001), the processing proceeds to step 1002. At step 1002, the determination circuit 121 determines whether or not an error flag is stored in the flag register 120. When it is determined at step 1002 that an error flag is not stored in the flag register 120 (No at step 1002), the step terminates at step 1009. When it is determined at step 1002 that an error flag is stored in the flag register 120 (Yes at step 1002), the processing proceeds to step 1003. At step 1003, the flag register 120 erases the error flag stored therein and the step terminates at step 1009.

In addition, when it is determined at step 1001 that an error signal is received from the comparison circuit 118 (Yes at step 1001), the processing proceeds to step 1004. At step 1004, the determination circuit 121 determines if an error flag is stored in the flag register 120. When it is determined at step 1004 that an error flag is not stored in the flag register 120 (No at step 1004), the processing proceeds to step 1005. At step 1005, the memory writing circuit 122 rewrites the coupling information in the address region A-1 and the address region A-2 which correspond to the first arithmetic circuit 114 and the second arithmetic circuit 115. At step 1006, the flag register 120 stores the error flag therein and the step terminates at step 1009.

Also, when it is determined at step 1004 that an error flag is stored in the flag register 120 (Yes at step 1004), the processing proceeds to step 1007. At step 1007, the memory writing circuit 122 writes the coupling information in the address region A-3 and the address region A-4, and respectively replaces the first arithmetic circuit 114 and the second arithmetic circuit 115 with the first standby circuit 116 and the second standby circuit 117. At step 1008, the flag register 120 erases the error flag stored therein and the step terminates at step 1009.

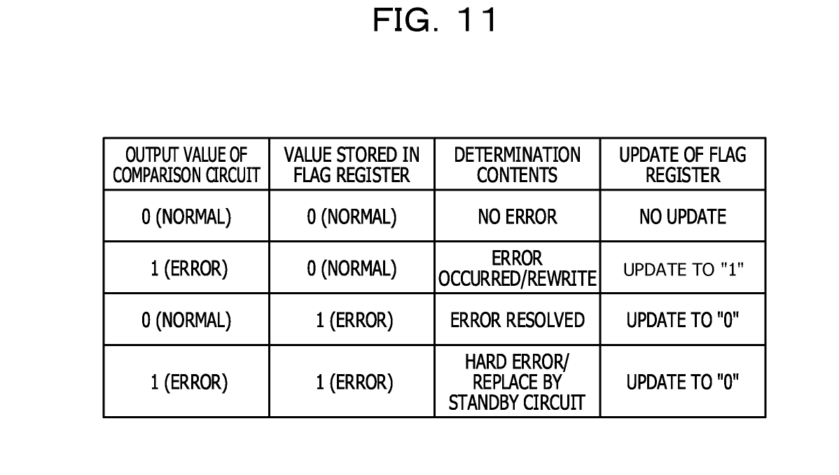

FIG. 11 is a table illustrating a coupling relationship between information which is used by the determination circuit 121 for determination and a determination result. It is assumed here that when the output results of the first arithmetic circuit 114 and the second arithmetic circuit 115 are the same, the comparison circuit 118 outputs a logical value “0”, and when the output results of the first arithmetic circuit 114 and the second arithmetic circuit 115 are different from each other, the comparison circuit 118 outputs a logical value “1” as an error signal. It is also assumed that when the error signal is received, the flag register 120 stores the logical value “1” as an error signal and stores the logical value “0” when the error signal is resolved.

In FIG. 11, when the output of the comparison circuit 118 is the logical value “0” and the value stored in the flag register 120 is also the logical value “0”, it is determined that an error does not occur in the first arithmetic circuit 114 and the second arithmetic circuit 115, and they are continuously usable. In addition, the flag register 120 is not updated.

When the output of the comparison circuit 118 is the logical value “1” and the value stored in the flag register 120 is the logical value “0”, it is determined that any error occurs in the first arithmetic circuit 114 or the second arithmetic circuit 115. In this case, the coupling information is rewritten in the address region A-1 corresponding to the first arithmetic circuit 114 and the address region A-2 corresponding to the second arithmetic circuit 115. Also, the value stored in the flag register 120 is updated to the logical value “1”.

When the output of the comparison circuit 118 is the logical value “0” and the value stored in the flag register 120 is the logical value “1”, it is determined that the error occurring in the first arithmetic circuit 114 or the second arithmetic circuit 115 is a soft error and the soft error is resolved. In this case, the value stored in the flag register 120 is updated to the logical value “0”.

When the output of the comparison circuit 118 is the logical value “1” and the value stored in the flag register 120 is the logical value “1”, it is determined that the error occurring in the first arithmetic circuit 114 or the second arithmetic circuit 115 is not a soft error but a hard error. In this case, the first arithmetic circuit 114 and the second arithmetic circuit 115 are respectively replaced by the first standby circuit 116 and the second standby circuit 117. Also, the value stored in the flag register 120 is updated to the logical value “0”.

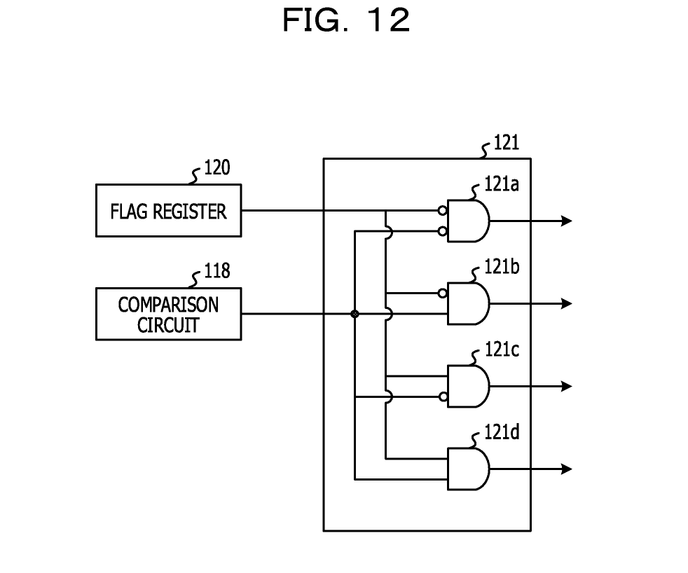

FIG. 12 is a diagram illustrating an example circuit configuration of the determination circuit 121. The value stored in the flag register 120 and the output value of the comparison circuit 118 are inputted to the determination circuit 121 as information for performing determination. The determination circuit 121 has AND circuits 121a, 121b, 121c, and 121d. An inverted signal of the value stored in the flag register 120 and an inverted signal of the output signal of the comparison circuit 118 are inputted to the AND circuit 121a. When the output of the AND circuit 121a becomes a logical value “1”, it is determined that a state in which an error does not occur in the first arithmetic circuit 114 and the second arithmetic circuit 115 is maintained.

An inverted signal of the value stored in the flag register 120 and the output signal of the comparison circuit 118 are inputted to the AND circuit 121b. When the output of the AND circuit 121b becomes the logical value “1”, it is determined that an error occurs in the first arithmetic circuit 114 or the second arithmetic circuit 115.

The value stored in the flag register 120 and an inverted signal of the output signal of the comparison circuit 118 are inputted to the AND circuit 121c. When the output of the AND circuit 121c becomes the logical value “1”, it is determined that the error is resolved by rewriting the coupling information.

The value stored in the flag register 120 and the output signal of the comparison circuit 118 are inputted to the AND circuit 121d. When the output of the AND circuit 121d becomes the logical value “1”, it is determined that the error is not resolved by rewriting the coupling information, in other words, a hard error occurs in the first arithmetic circuit 114 or the second arithmetic circuit 115.

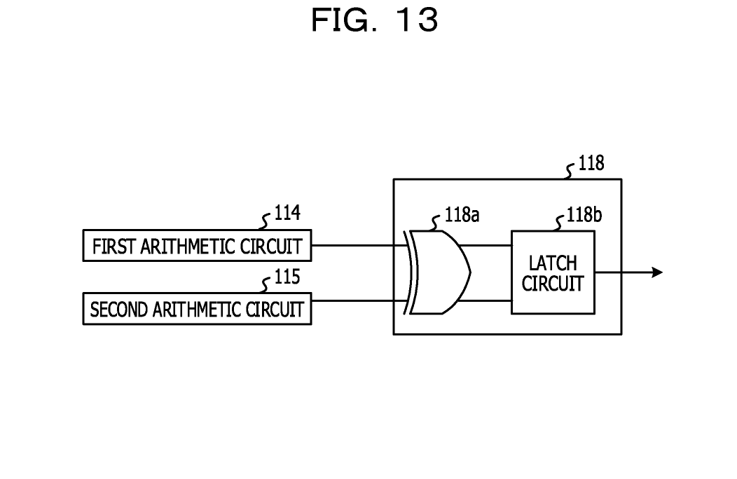

FIG. 13 is a diagram illustrating an example circuit configuration of the comparison circuit 118. The comparison circuit 118 has an exclusive OR circuit 118a and a latch circuit 118b. The exclusive OR circuit 118a outputs a logical value “0” when logical values of multiple signals to be inputted are the same, and outputs a logical value “1” when the logical values of the multiple signals to be inputted are different from one another. Also, the latch circuit 118b provided in the downstream of the exclusive OR circuit 118a stores and outputs the inputted logical values. The latch circuit 118b fetches inputted data in synchronization of a startup edge of a clock, for example.

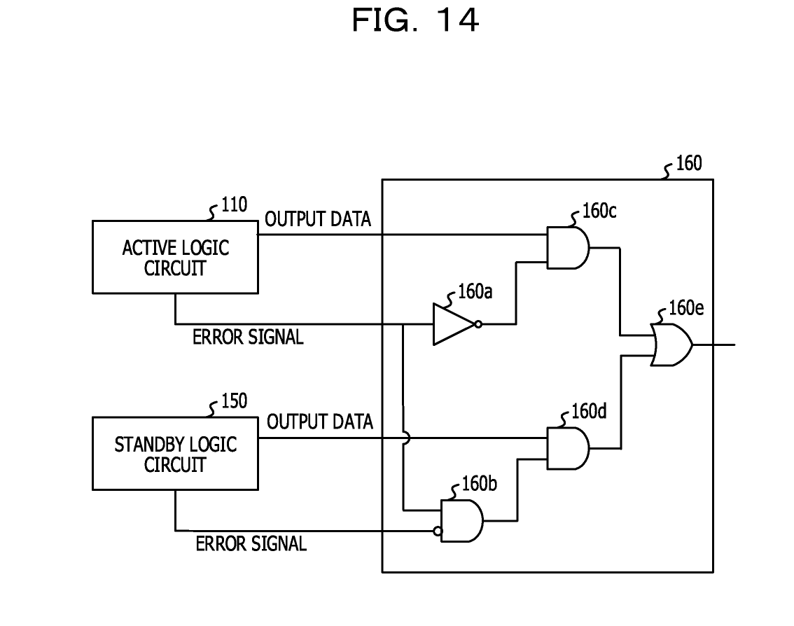

FIG. 14 is a diagram illustrating an example circuit configuration of the selection circuit 160 which selects any one of output data of the active logic circuit 110 and the output data of the standby logic circuit 150. It is assumed here that the standby logic circuit 150 has substantially the same configuration with the configuration described in FIGS. 6 to 13. The selection circuit 160 has a NOT circuit 160a, AND circuits 160b, 160c, 160d, and an OR circuit 160e. Output data of the active logic circuit 110 is inputted to the AND circuit 160c. When an error signal of the active logic circuit 110 is a logical value “0”, in other words, an error does not occur in the output of the active logic circuit 110, an output of the NOT circuit 160a becomes a logical value “1” and the AND circuit 160c outputs output data of the active logic circuit 110. In this case, the outputs of the AND circuit 160b and the AND circuit 160d are fixed as the logical value “0”, and the output data of the active logic circuit 110 is outputted from the OR circuit 160e in the end of the stream.

On the other hand, when the error signal of the active logic circuit 110 is a logical value “1”, in other words, when an error occurs in the active logic circuit 110, the output of the NOT circuit 160a becomes the logical value “0”, and the output of the AND circuit 160c is fixed as the logical value “0”. In this case, the error signal of the active logic circuit 110 has the logical value “1”. Thus, when the error signal of the standby logic circuit 150 has a logical value “0”, the output of the AND circuit 160b is fixed as the logical value “1” and the AND circuit 160d outputs output data of the standby logic circuit 150 and the output data of the standby logic circuit 150 is outputted from the OR circuit 160e.

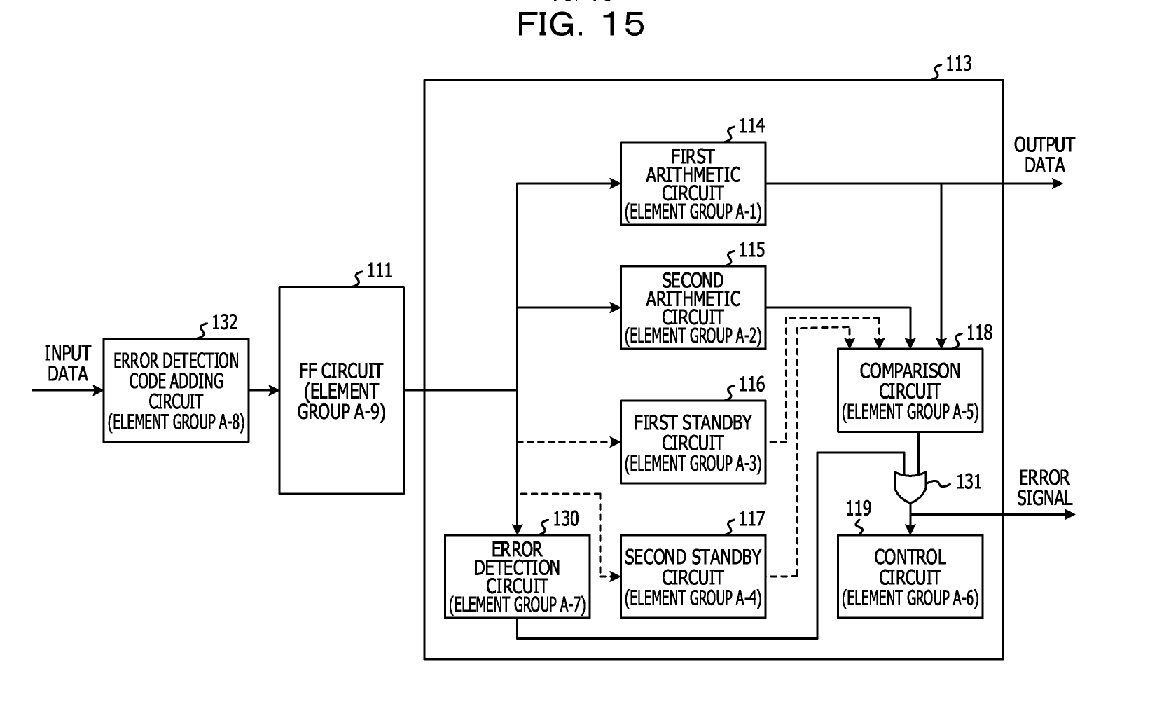

FIG. 15 is a diagram illustrating a modification of the logic circuit illustrated in FIGS. 5 and 6. The same reference numerals are given to denote the same configuration as that described above and the description thereof is omitted. The FF circuit 111 provided in the upstream of the combinational circuit 113 is formed by coupling logic elements and the like included in the element group A-9. The coupling relationship of the element group A-9 is specified by writing the coupling relationship for the FF circuit 111 in a predetermined address region of the memory 200. For this reason, it is supposed that a soft error occurs in the coupling information of the FF circuit 111. When a soft error occurs in the coupling information of the FF circuit 111, data to be inputted to the FF circuit 111 and data to be outputted from the FF circuit 111 become different from each other. For this reason, in this modification, an error detection code adding circuit 132 is provided in a transmission source of the data to the FF circuit 111, so that an error detection code is added to the data. Then, an error detection circuit 130 is provided in the downstream of the FF circuit 111, so that an error may be detected even when an error occurs in the FF circuit 111. The error detection code adding circuit 132 is formed by an element group A-8 and the error detection circuit 130 is formed by an element group A-7. As an error detection code, a CRC code or a parity code is applicable. Also, an error detection code capable of performing an error correction in addition to the error detection is applicable to the present modification. In this modification, when an error is detected in at least one of the comparison circuit 118 and error detection circuit 130, the control circuit 119 executes the processing flow described in FIG. 10. In this case, coupling information of the arithmetic circuits are rewritten in the address regions A-1 and A-2 which respectively correspond to the first arithmetic circuit 114 and the second arithmetic circuit 115. Furthermore, the coupling information of the FF circuit 111 is rewritten in the address region corresponding to the FF circuit 111. It is noted that although it is not illustrated, as long as a standby circuit is provided for the FF circuit 111, when a hard error occurs in the elements configuring the FF circuit 111, the FF circuit 111 is replaceable by the standby circuit.

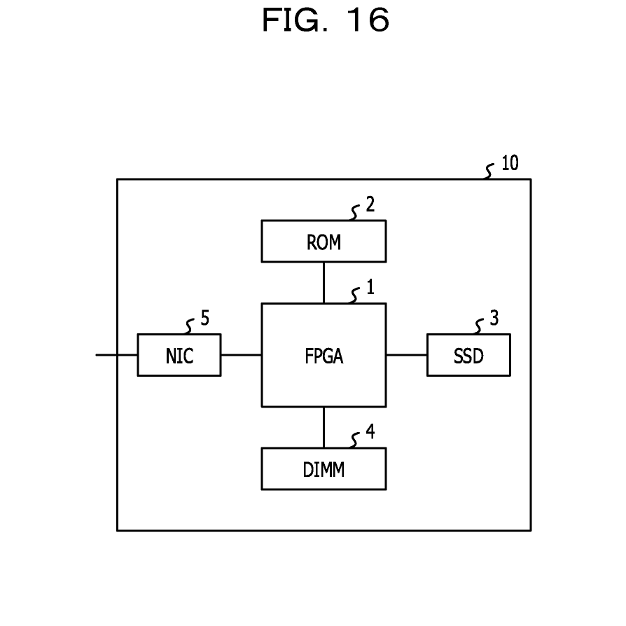

FIG. 16 is a diagram illustrating an example utility form of the disclosed FPGA 1. In the example illustrated in FIG. 16, the FPGA 1 is mounted on a computer 10 such as a blade server, and is used as a controller for a solid state drive (SSD) 3 which is a storage device, or a dual inline memory module (DIMM) 4 which is a main storage memory. The computer 10 is coupled with other computer, for example, a management server via an NIC 5. The FPGA 1 writes the data received via the NIC 5 in the SSD 3 and the DIMM 4 or reads and writes the data between the SSD 3 and the DIMM 4.

The configuration and the operation of the FPGA 1 is described above as an embodiment, but the present disclosure is not limited to the disclosed embodiment. For example, as the memory 200, a memory device capable of storing the coupling information of the elements is applicable besides the SRAM described in the embodiment. Also, each of the multiple address regions described in the embodiment may be configured in an individual memory or may be configured by using different address space in a shared memory. Also, in the present disclosure, described is an example in which the selection circuit 160, the FF circuit 111, the FF circuit 112, the comparison circuit 118, the control circuit 119, the error detection code adding circuit 132, and the error detection circuit 130 are formed by the element groups included in the programmable logic circuit 100. However, these circuits do not necessarily have to be formed by using the programmable logic circuit, but may be a dedicated circuit which is formed in a fixed manner in a stage of manufacturing the FPGA 1.

Also, in the embodiment, the redundant logic circuit using the active logic circuit 110 and the standby logic circuit 150 is described as an example, but the logic circuit does not has to be redundant in the disclosure. The present disclosure also has such an advantage that both a soft error and a hard error are detectable in a logic circuit without the standby logic circuit 150 and a recovery operation may be made on the both errors.

It is noted that in the embodiment, the FPGA is described as an example, but the disclosed technology is not limited to the FPGA, but is widely applicable to a PLD capable of performing control on a coupling state of multiple logic elements based on the coupling information.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A circuit comprising:
a memory including a first memory region and a second memory region each configured to store coupling information specifying a coupling relationship of a plurality of logic elements;
a first logic circuit including a plurality of first logic elements included in the plurality of logic elements which are coupled with each other based on the coupling information stored in the first memory region;
a second logic circuit including a plurality of second logic elements included in the plurality of logic elements which are coupled with each other based on the coupling information stored in the second memory region;
a writing circuit configured to write the coupling information in each of the first memory region and the second memory region when a first output data of the first logic circuit based on a first input data into the first logic circuit does not identify to a second output data of the second logic circuit based on the first input data into the second logic circuit; and
a determination circuit configured to determine whether or not the first output data identifies to the second output data after the coupling information is written in each of the first memory region and the second memory region.

2. The circuit according to claim 1, further comprising:
a third memory region included in the memory and configured to store the coupling information;
a third logic circuit including a plurality of third logic elements included in the plurality of logic elements which are coupled with each other based on the coupling information stored in the third memory region; and
a selection circuit configured to selectively output one of the first output data and a third output data of the third logic circuit, wherein
the first input data is received by the third logic circuit, and the selection circuit selects the third output data when the first output data does not identify to the second output data after the coupling information is written in each of the first memory region and the second memory region.

3. The circuit according to claim 2, further comprising:
a fourth memory region included in the memory;
a fifth memory region included in the memory;
a plurality of fourth logic elements included in the plurality of logic elements whose coupling state is specified based on information stored in the fourth memory region; and
a plurality of fifth logic elements included in the plurality of logic elements whose coupling state is specified based on information stored in the fifth memory region, wherein
the writing circuit writes the coupling information in each of the fourth memory region and the fifth memory region when the first output data does not identify to the second output data after the coupling information is written in each of the first memory region and the second memory region, and
the plurality of fourth logic elements and the plurality of fifth logic elements form a fourth logic circuit and a fifth logic circuit respectively by writing the coupling information into each of the fourth memory region and the fifth memory region.

4. The circuit according to claim 3, further comprising:
a comparison circuit configured to compare a fourth output data of the fourth logic circuit and a fifth output data of the fifth logic circuit, wherein
the selection circuit selectively outputs one of the third output data and the fourth output data.

5. The circuit according to claim 1, further comprising:
a nonvolatile memory configured to store the coupling information, wherein
writing the coupling information in the first memory region and the second memory region is performed by writing the coupling information stored in the nonvolatile memory into the first memory region and the second memory region.

6. The circuit according to claim 5, wherein
writing the coupling information in the fourth memory region and the fifth memory region is performed by writing the coupling information stored in the nonvolatile memory into the fourth memory region and the fifth memory region.

7. The circuit according to claim 1, wherein
the memory is a static random access memory.

8. A method of controlling a circuit including a plurality of logic elements and a memory configured to store coupling information specifying a coupling relationship of the plurality of logic elements, the method comprising:
inputting a first data to a first logic circuit and a second logic circuit, wherein the first logic circuit is formed by coupling a plurality of first logic elements of the plurality of logic elements based on the coupling information stored in a first memory region of the memory and the second logic circuit is formed by coupling a plurality of second logic elements of the plurality of logic elements based on the coupling information stored in a second memory region of the memory;
outputting a signal indicating whether or not a first output data of the first logic circuit identifies to a second output data of the second logic circuit;
when the signal indicates that the first output data does not identify the second output data, writing the coupling information in each of the first memory region and the second memory region; and
determining whether or not the first output data identifies to the second output data after writing the coupling information in each of the first memory region and the second memory region.

9. The method of controlling the circuit according to claim 8, further comprising:
selectively outputting one of the first output data and a third output data of a third logic circuit formed by coupling a plurality of third logic elements of the plurality of logic elements based on the coupling information stored in a third memory region of the memory.

10. The method of controlling the circuit according to claim 8, further comprising:
writing the coupling information in each of a fourth memory region and a fifth memory region of the memory when the first output data does not identify to the second output data even after the coupling information is written in each of the first memory region and the second memory region, wherein
a fourth logic circuit is formed by coupling a plurality of fourth logic elements included in the plurality of logic elements based on the coupling information written in the fourth memory region and a fifth logic circuit is formed by coupling a plurality of fifth logic elements included in the plurality of logic elements based on the coupling information written in the fifth memory region.

11. The method of controlling the circuit according to claim 8, wherein
writing the coupling information in the first memory region and the second memory region is performed by writing the coupling information stored in a nonvolatile memory included in the circuit into the first memory region and the second memory region.

12. The method of controlling the circuit according to claim 8, wherein
the memory is a static random access memory.
